(19) United States
(12) Patent Application Publication
(10) Pub. No.: US 2026/0056114 A1
(43) Pub. Date: Feb. 26, 2026

(54) MEASUREMENT APPARATUS, MEASUREMENT METHOD, AND CALIBRATION METHOD

(71) Applicants: THE UNIVERSITY OF TOKYO, Tokyo (JP); Tokyo Electron Limited, Tokyo (JP)

(72) Inventors: Takao OKABE, Tokyo (JP); Shinichi TANABE, Tokyo (JP); Toshikazu AKIMOTO, Tokyo (JP); Naoki UMESHITA, Tokyo (JP)

(73) Assignees: THE UNIVERSITY OF TOKYO, Tokyo (JP); Tokyo Electron Limited, Tokyo (JP)

(21) Appl. No.: 19/378,369

(22) Filed: Nov. 4, 2025

Related U.S. Application Data
(63) Continuation of application No. PCT/JP2024/016631, filed on Apr. 30, 2024.

(30) Foreign Application Priority Data
May 11, 2023 (JP) 2023-078642

(51) Int. Cl. G01N 19/02; H01L 21/683

(52) U.S. Cl. CPC G01N 19/02; H01L 21/6831

(57) ABSTRACT

A measurement apparatus includes a measurement unit and a controller. The measurement unit is able to measure force needed to shift a substrate on a substrate adsorption unit that is able to adsorb the substrate, in an adsorbed state in which the substrate is adsorbed by the substrate adsorption unit. The controller calculates adsorption force of the substrate adsorption unit based on the force measured by the measurement unit.

### CROSS-REFERENCE TO RELATED APPLICATIONS

This application is a continuation of International Application No. PCT/JP2024/016631, filed on Apr. 30, 2024 which claims the benefit of priority of the prior Japanese Patent Application No. 2023-078642, filed on May 11, 2023, the entire contents of each are incorporated herein by reference.

### FIELD

Exemplary embodiments disclosed herein relate to a measurement apparatus, a measurement method, and a calibration method.

### BACKGROUND

Japanese Laid-open Patent Publication No. 2012-204447 below discloses “an electrostatic chuck that includes an electrode made of a conductive material and embedded in a plate-shaped silica glass and that adsorbs an adsorption object by using one principal plane as an adsorption surface, where the electrostatic chuck has a shape in which a distance between the electrode and the adsorption surface reaches a maximum value in the center of the adsorption surface, changes continuously from the center of the adsorption surface to an outer periphery of the adsorption surface, and reaches a minimum value at the outer periphery of the adsorption surface, and surface roughness of the adsorption surface is increased in an outer peripheral region as compared to a central region of the adsorption surface”.

The present disclosure provides a technology for quantitatively measuring adsorption force with good reproducibility.

### SUMMARY

In an embodiment of a present disclosure, a measurement apparatus includes: a measurement unit that is able to measure force needed to shift a substrate on a substrate adsorption unit that is able to adsorb the substrate, in an adsorbed state in which the substrate is adsorbed by the substrate adsorption unit; and a controller that calculates adsorption force of the substrate adsorption unit based on the force measured by the measurement unit.

### BRIEF DESCRIPTION OF DRAWINGS

FIG. 1 is a diagram schematically illustrating an example of a configuration of a measurement apparatus according to a first embodiment;

FIG. 2 is a diagram schematically illustrating an example of a configuration in the vicinity of a lower part of the measurement apparatus according to the first embodiment;

FIG. 3 is a flowchart illustrating an example of a flow of measurement processing according to the first embodiment;

FIG. 4 is a diagram schematically illustrating an example of a configuration of a substrate processing apparatus according to a second embodiment;

FIG. 5 is a diagram schematically illustrating a state in which a transfer mechanism presses a side surface of a substrate; and

FIG. 6 is a flowchart illustrating an example of the flow of calibration processing according to the second embodiment.

### DESCRIPTION OF EMBODIMENTS

Exemplary embodiments of a measurement apparatus, a measurement method, and a calibration method disclosed in the present application will be explained below in detail with reference to the accompanying drawings. The measurement apparatus, the measurement method, and the calibration method disclosed below are not limited to the embodiments explained below.

Some substrate processing apparatuses are configured to adsorb and hold a substrate, such as a semiconductor wafer, by an electrostatic chuck. As a technique of measuring adsorption force of the electrostatic chuck, for example, a technique of drawing the substrate adsorbed by the electrostatic chuck in a vertical direction and measuring the adsorption force from force with which the substrate is removed is known. Further, for example, a technique of supplying gas between the electrostatic chuck and the adsorbed substrate and evaluating the adsorption force by gas pressure at the time the substrate is removed is known.

However, in each of the techniques, warpage or slippage occurs on the substrate in a process of vertically drawing the substrate with respect to the electrostatic chuck and a process of removing the substrate from a part is included. Therefore, in each of the techniques, measured adsorption force varies depending on the difference in the way of removal of the substrate, so that it is difficult to quantitatively measure the adsorption force with good reproducibility.

### First Embodiment

### Configuration of Apparatus

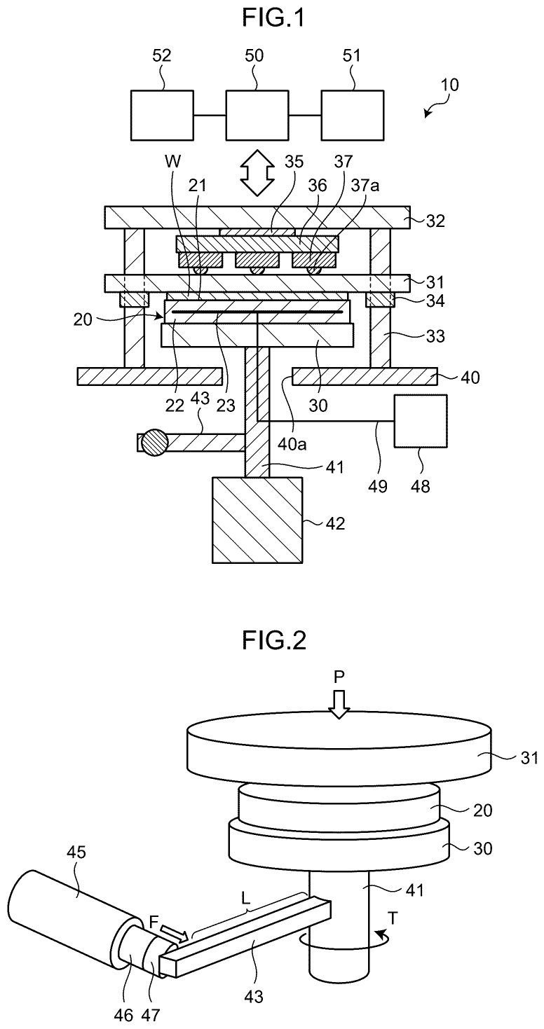

A first embodiment will be described. FIG. 1 is a diagram schematically illustrating an example of a configuration of a measurement apparatus 10 according to the first embodiment. The measurement apparatus 10 is an apparatus that measures adsorption force of an electrostatic chuck 20 that is a measurement target. In the present embodiment, the electrostatic chuck 20 corresponds to a substrate adsorption unit of the present disclosure. As will be described later, the electrostatic chuck 20 is an object that is detached from a substrate processing apparatus that is actually operated to measure temporal change of adsorption force or an object that is not yet mounted on the substrate processing apparatus due to pre-shipment inspection or the like.

In the electrostatic chuck 20, a placing surface 21 for placing a substrate W, such as a semiconductor wafer, is formed. The electrostatic chuck 20 is configured to be able to adsorb the substrate W that is placed on the placing surface 21. For example, the electrostatic chuck 20 includes a ceramic member 22 and an electrostatic electrode 23 that is disposed in the ceramic member 22. The electrostatic chuck 20 electrostatically adsorbs the substrate W by application of voltage to the electrostatic electrode 23.

The measurement apparatus 10 is configured to be able to measure force needed to shift the substrate W on the electrostatic chuck 20 in an adsorption state in which the substrate W is adsorbed by the electrostatic chuck 20. The measurement apparatus 10 is configured to calculate adsorption force of the electrostatic chuck 20 based on the measured force.

For example, the measurement apparatus 10 includes a stage 30 that holds the electrostatic chuck 20. The electrostatic chuck 20 is fixed to the stage 30 by bonding or a mechanical fixing mechanism, such as a bolt.

The measurement apparatus 10 is configured to be able to press the substrate W against the electrostatic chuck 20 that is held by the stage 30. For example, the measurement apparatus 10 includes a substrate holding plate 31 and a fixing plate 32. The substrate holding plate 31 and the fixing plate 32 are formed to be wider than the stage 30. The substrate W is fixed to a lower surface of the substrate holding plate 31 by bonding or a mechanical fixing mechanism, such as a bolt.

The substrate holding plate 31 is disposed above the stage 30. The fixing plate 32 is disposed above the substrate holding plate 31. The substrate holding plate 31 and the fixing plate 32 are supported by a plurality of poles 33. For example, the fixing plate 32 is fixed to upper ends of the plurality of poles 33. In the substrate holding plate 31, through holes through which the poles 33 penetrate are formed. Slight gaps are formed between the substrate holding plate 31 and the poles 33 that pass through the through holes such that the substrate holding plate 31 is able to move up and down along the poles 33. Rings 34 are provided on the poles 33 on the lower side of the substrate holding plate 31. The rings 34 are fixed to the poles 33. Downward movement of the substrate holding plate 31 is restricted by the rings 34. A lower end of each of the poles 33 is fixed to a base 40 that is provided below the stage 30.

At a side of a lower surface of the fixing plate 32, a plate 36 is provided via a pressure sensor 35. A plurality of contact members 37 are provided on a lower surface of the plate 36. On lower sides of the contact members 37, semicircular protrusions 37a are formed. The entire contact members 37 or portions corresponding to the protrusions 37a are made of elastic member.

A support unit 41 is connected to a center of a lower surface of the stage 30. The support unit 41 is formed in a cylindrical shape, passes through an opening 40a formed in the base 40, and is connected to a lifting-lowering mechanism 42 that is provided below the base 40. The lifting-lowering mechanism 42 rotatably supports the support unit 41 and is configured to be able to lift and lower the support unit 41. The lifting-lowering mechanism 42 lifts the support unit 41 to lift the stage 30. In the present embodiment, the stage 30, the substrate holding plate 31, the fixing plate 32, the poles 33, the plate 36, the contact members 37, the support unit 41, and the lifting-lowering mechanism 42 correspond to a pressing mechanism of the present disclosure. Furthermore, the pressure sensor 35 corresponds to a pressure measurement unit of the present disclosure.

On the support unit 41, an arm 43 is provided on a side surface in a vertical direction with respect to a central axis of the support unit 41. The arm 43 is fixed to the support unit 41. The support unit 41 rotates along with movement of the arm 43.

FIG. 2 is a diagram schematically illustrating an example of a configuration in the vicinity of a lower part of the measurement apparatus 10 according to the first embodiment. An actuator 45, such as a gas cylinder, is provided in the measurement apparatus 10. The actuator 45 allows extension and contraction of a rod 46. The actuator 45 is provided at a position corresponding to an end portion of the arm 43. In the actuator 45, a leading end of the rod 46 is connected to the arm 43. A distance from a rotation axis of the support unit 41 to a connection position between the arm 43 and the rod 46 is denoted by L. By extension and contraction of the rod 46 of the actuator 45, torque is applied to the support unit 41 via the arm 43. By application of the torque, the support unit 41 rotates about the central axis as the rotation axis. In the present embodiment, the stage 30, the support unit 41, the arm 43, and the actuator 45 correspond to a rotation mechanism of the present disclosure.

A pressure sensor 47 is provided in a connection portion between the rod 46 and the arm 43. The pressure sensor 47 measures pressure at which the rod 46 presses the arm 43 and measures the torque for rotating the electrostatic chuck 20. In the present embodiment, the pressure sensor 47 corresponds to a measurement unit of the present disclosure.

Referring back to FIG. 1, the measurement apparatus 10 includes a direct-current power supply 48. The direct-current power supply 48 is connected to the electrostatic electrode 23 of the electrostatic chuck 20 via a wire 49. The direct-current power supply 48 applies voltage to the electrostatic electrode 23 via the wire 49. The electrostatic chuck 20 generates electrostatic force and adsorbs the substrate W by application of voltage from the direct-current power supply 48 to the electrostatic electrode 23.

The measurement apparatus 10 includes a controller 50. A user interface 51 and a storage 52 are connected to the controller 50.

The user interface 51 includes an operation unit, such as a keyboard, that allows a user to perform command input operation for operating the measurement apparatus 10, and a display unit, such as a display, that visualizes and displays an operating state and a measurement result of the measurement apparatus 10.

The storage 52 stores therein a control program (software) for executing various kinds of processing performed by the measurement apparatus 10 and data, such as processing parameters. Meanwhile, the control program and the data may be stored in a computer readable computer recording medium (for example, a hard disk, an optical disk such as a digital versatile disk (DVD), a flexible disk, a semiconductor memory, or the like). Further, the control program and the data may be stored in a different apparatus and may be read and used online via a dedicated line, for example.

The controller 50 is, for example, a computer that includes a processor, a memory, and an input output interface. The controller 50 controls each of the units of the measurement apparatus 10 via the input output interface. For example, the controller 50 controls the direct-current power supply 48 to control voltage that is applied from the direct-current power supply 48 to the electrostatic electrode 23. Further, the controller 50 controls the lifting-lowering mechanism 42 to control lifting and lowering of the stage 30. Furthermore, the controller 50 controls the actuator 45 to control rotation of the stage 30.

The controller 50 reads the control program and the data stored in the storage 52 onto a memory based on an instruction or the like from the user interface 51, and causes the processor to execute processing of the read control program. The controller 50 controls each of the units of the measurement apparatus 10 via the input output interface based on the control program and performs various kinds of processing including measurement processing (to be described later).

Operation of the measurement apparatus 10 will be described below.

In the measurement apparatus 10, the electrostatic chuck 20 that is a measurement target of the adsorption force is fixed to the stage 30. Further, the substrate W that is used for measurement of the adsorption force is fixed to the lower surface of the substrate holding plate 31. The substrate W may be a substrate that is actually subjected to processing by a substrate processing apparatus that is mounted with the electrostatic chuck 20. The substrate, such as a semiconductor wafer, is subjected to various kinds of processes, so that a shape change, such as deflection, occurs. By adopting, as the substrate W, a substrate that is to be actually subjected to processing by the substrate processing apparatus, it is possible to more accurately measure the adsorption force.

The measurement apparatus 10 presses the substrate W against the electrostatic chuck 20. For example, the controller 50 controls the lifting-lowering mechanism 42 and lifts the support unit 41 and the stage 30 by the lifting-lowering mechanism 42. When the stage 30 is lifted, an upper surface of the electrostatic chuck 20 held by the stage 30 comes into contact with the substrate W held by the substrate holding plate 31. Further, when the stage 30 is further lifted, the substrate holding plate 31 is lifted while the electrostatic chuck 20 and the substrate W are in contact with each other, and an upper surface of the substrate holding plate 31 comes into contact with each of the contact members 37 of the fixing plate 32. Furthermore, when the lifting-lowering mechanism 42 further applies lifting force to the support unit 41, downward stress is applied from the fixing plate 32 to the substrate holding plate 31 via each of the contact members 37. Accordingly, downward pressure is applied from the substrate W held by the substrate holding plate 31 to the placing surface 21 of the electrostatic chuck 20, and the substrate W is pressed against the placing surface 21 of the electrostatic chuck 20. The substrate holding plate 31 is configured to be able to move up and down along the poles 33 and apply downward stress to the substrate holding plate 31 via the plurality of contact members 37, so that the substrate holding plate 31 is able to approximately uniformly press the substrate W against the placing surface 21 of the electrostatic chuck 20. Pressing force related to the configuration of the first embodiment is set to, for example, standard atmospheric pressure+0.1 MPa at a maximum.

The measurement apparatus 10 applies force to rotate the electrostatic chuck 20 and measures torque at which the electrostatic chuck 20 starts to rotate in both of an adsorbed state in which the electrostatic chuck 20 adsorbs the substrate W and a non-adsorbed state in which the electrostatic chuck 20 does not adsorb the substrate W. For example, the controller 50 controls the direct-current power supply 48 and turns on and off voltage applied to the electrostatic electrode 23 to switch between the adsorbed state and the non-adsorbed state of the electrostatic chuck 20. A voltage value of voltage applied in the adsorbed state may be input from the user interface 51 or may be stored in the storage 52 in advance. The controller 50 controls the actuator 45 in each of the adsorbed state and the non-adsorbed state and extends the rod 46 of the actuator 45 to press the arm 43 and apply force for rotating the support unit 41, so that the stage 30 and the electrostatic chuck 20 are rotated. The controller 50 causes the pressure sensor 47 to measure pressure at which the electrostatic chuck 20 starts to rotate in both of the adsorbed state and the non-adsorbed state. The controller 50 calculates torque at which the electrostatic chuck 20 starts to rotate in each of the adsorbed state and the non-adsorbed state from the measured pressure in each of the adsorbed state and the non-adsorbed state and a distance L from the rotation axis of the support unit 41 to the connection position between the arm 43 and the rod 46. For example, the controller 50 multiplies the measured pressure in each of the adsorbed state and the non-adsorbed state by the distance L from the rotation axis of the support unit 41 to the connection position between the arm 43 and the rod 46, and calculates the torque at which the electrostatic chuck 20 starts to rotate in each of the adsorbed state and the non-adsorbed state.

Furthermore, the measurement apparatus 10 measures the pressure at which the substrate W is pressed against the electrostatic chuck 20. For example, the controller 50 causes the pressure sensor 35 to measure the pressure.

The measurement apparatus 10 calculates the adsorption force of the electrostatic chuck 20 from the torque in the adsorbed state, the torque in the non-adsorbed state, and the pressure at which the substrate W is pressed against the electrostatic chuck 20.

Here, the torque at which the electrostatic chuck 20 starts to rotate in the adsorbed state is denoted by T, the torque at which the electrostatic chuck 20 starts to rotate in the non-adsorbed state is denoted by T′, and the pressure at which the substrate W is pressed against the electrostatic chuck 20 is denoted by P. Further, the adsorption force of the electrostatic chuck 20 is denoted by N, and a dynamic friction coefficient between the electrostatic chuck 20 and the substrate W is denoted by μ. A relationship represented by Expression (1-1) below holds in the non-adsorbed state, and a relationship represented by Expression (1-2) below holds in the adsorbed state.

$${T}^{′} = μ / P \qquad ( 1 - 1 )$$

$$T = μ / ( P + N ) \qquad ( 1 - 2 )$$

If μ is removed and converted from Expressions (1-1) and (1-2), Expression (2) below is obtained.

$$N = P ( {T}^{′} / T - 1 ) \qquad ( 2 )$$

Further, assuming that a diameter of the substrate W is denoted by D, a dynamic friction coefficient μ has a relationship represented by Expression (3) below.

$$μ = ( 2 / D / P ) / T \qquad ( 3 )$$

The controller 50 calculates adsorption force N of the electrostatic chuck 20 by Expression (2) based on torque T in the adsorbed state, torque T′ in the non-adsorbed state, and pressure P at which the substrate W is pressed against the electrostatic chuck 20. Further, the controller 50 calculates the dynamic friction coefficient μ by Expression (3) based on a diameter D of the substrate W, the torque T in the adsorbed state, and the pressure P at which the substrate W is pressed against the electrostatic chuck 20. The diameter D of the substrate W may be input from the user interface 51 or may be stored in the storage 52 in advance.

The controller 50 outputs the calculated adsorption force N of the electrostatic chuck 20 and the calculated dynamic friction coefficient μ. For example, the controller 50 displays the adsorption force N of the electrostatic chuck 20 and the dynamic friction coefficient μ on the display unit of the user interface 51.

In this manner, the measurement apparatus 10 applies rotation force to the electrostatic chuck 20 that is in contact with the substrate W, measures force (torque) needed to shift the substrate W on the electrostatic chuck 20, and calculates the adsorption force N of the electrostatic chuck 20 based on the measured force. The measurement apparatus 10, by measuring the force needed for shift without drawing the substrate W in the vertical direction with respect to the electrostatic chuck 20 at the time of measuring the adsorption force, is able to measure the force needed for shift with good reproducibility and quantitatively measure the adsorption force of the electrostatic chuck 20 with good reproducibility.

In this manner, it is possible to quantitatively measure the adsorption force of the electrostatic chuck 20 with good reproducibility, so that it is possible to measure a change in the adsorption force due to application voltage applied to the electrostatic electrode 23. With this configuration, it is possible to obtain the application voltage that is appropriate for adsorption of the substrate W. Furthermore, by periodically extracting the electrostatic chuck 20 from the substrate processing apparatus, causing the measurement apparatus 10 to measure the adsorption force of the electrostatic chuck 20, and obtaining a temporal change of the adsorption force, it is possible to recognize a replacement timing of the electrostatic chuck 20. When a plurality of substrate processing apparatuses that perform similar substrate processing are present, by obtaining a temporal change of the adsorption force of the electrostatic chuck 20 in any of the substrate processing apparatuses, it is possible to recognize replacement timings of the electrostatic chucks 20 of the other substrate processing apparatuses. Further, even when voltage applied to the electrostatic electrode 23 is turned off, the adsorption force of the electrostatic chuck 20 decreases over time since the turning off. To cope with this, by measuring a temporal change of the adsorption force of the electrostatic chuck 20 since turning off of the voltage applied to the electrostatic electrode 23, it is possible to obtain an appropriate timing for lifting the substrate W from the electrostatic chuck 20.

### Flow of Measurement Processing

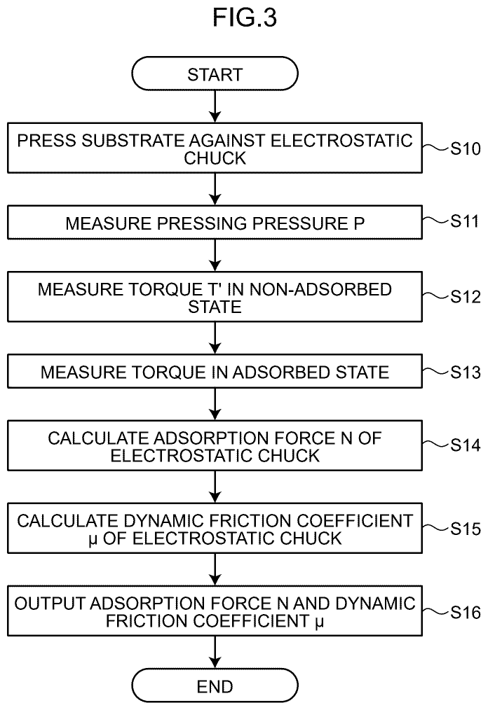

A flow of measurement processing including the measurement method of the present disclosure will be described below. FIG. 3 is a flowchart illustrating an example of a flow of measurement processing according to the first embodiment.

The measurement apparatus 10 presses the substrate W against the electrostatic chuck 20 (Step S10). For example, the controller 50 controls the lifting-lowering mechanism 42 and causes the lifting-lowering mechanism 42 to lift the support unit 41 and the stage 30 and press the electrostatic chuck 20 against the placing surface 21 by the substrate W that is held by the substrate holding plate 31.

The measurement apparatus 10 measures the pressure P at which the substrate W is pressed against the electrostatic chuck 20 (Step S11). For example, the controller 50 measures the pressure P by the pressure sensor 35.

The measurement apparatus 10 measures the torque T′ at which the electrostatic chuck 20 starts to rotate in the non-adsorbed state (Step S12). For example, the controller 50 controls the direct-current power supply 48 and turns off voltage applied to the electrostatic electrode 23 to switch the electrostatic chuck 20 to the non-adsorbed state. The controller 50 extends the rod 46 of the actuator 45 to cause the rod 46 to press the arm 43 and apply force to rotate the support unit 41, to thereby rotate the stage 30 and the electrostatic chuck 20. The controller 50 causes the pressure sensor 47 to measure the pressure at which the stage 30 and the electrostatic chuck 20 start to rotate. The controller 50 multiplies the measured pressure by the distance L to calculate the torque T′ at which the electrostatic chuck 20 starts to rotate in the non-adsorbed state.

The measurement apparatus 10 measures the torque T at which the electrostatic chuck 20 starts to rotate in the adsorbed state (Step S13). For example, the controller 50 controls the direct-current power supply 48 and applies voltage to the electrostatic electrode 23 to switch the electrostatic chuck 20 to the adsorbed state. The controller 50 extends the rod 46 of the actuator 45 to cause the rod 46 to press the arm 43 and apply force to rotate the support unit 41, to thereby rotate the stage 30 and the electrostatic chuck 20. The controller 50 causes the pressure sensor 47 to measure the pressure at which the stage 30 and the electrostatic chuck 20 start to rotate.

The controller 50 multiplies the measured pressure by the distance L to calculate the torque T at which the electrostatic chuck 20 starts to rotate in the adsorbed state.

Meanwhile, Step S11 may be performed in parallel with Step S12 or Step S13. Further, processing order of Step S12 and Step S13 may be reversed.

The measurement apparatus 10 calculates the adsorption force N of the electrostatic chuck 20 (Step S14). For example, the controller 50 calculates the adsorption force N of the electrostatic chuck 20 by Expression (2) described above based on the torque T in the adsorbed state, the torque T′ in the non-adsorbed state, and the pressure P at which the substrate W is pressed against the electrostatic chuck 20.

The measurement apparatus 10 calculates the dynamic friction coefficient μ of the electrostatic chuck 20 (Step S15). For example, the controller 50 calculates the dynamic friction coefficient μ by Expression (3) described above based on the diameter D of the substrate W, the torque T in the adsorbed state, and the pressure P at which the substrate W is pressed against the electrostatic chuck 20.

The measurement apparatus 10 outputs the adsorption force N and the dynamic friction coefficient μ of the electrostatic chuck 20 (Step S16), and terminates the process. For example, the controller 50 displays the adsorption force N and the dynamic friction coefficient μ of the electrostatic chuck 20 on the display unit of the user interface 51.

With this configuration, the user is able to recognize the adsorption force N and the dynamic friction coefficient μ of the electrostatic chuck 20.

### Second Embodiment

### Configuration of Apparatus

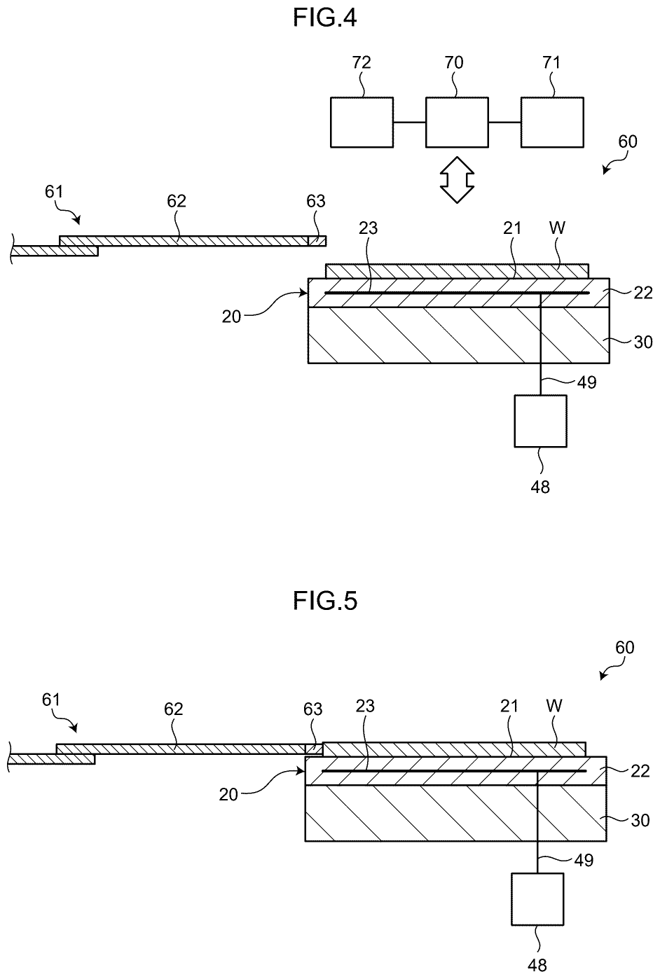

A second embodiment will be described below. In the second embodiment, a case will be described in which the configuration of the measurement apparatus of the present disclosure is applied to a substrate processing apparatus. FIG. 4 is a diagram schematically illustrating an example of a configuration of a substrate processing apparatus 60 according to the second embodiment. The substrate processing apparatus 60 is an apparatus that performs various kinds of substrate processing, such as etching, film formation, or ashing. The substrate processing apparatus 60 may be a vacuum processing apparatus that includes an airtightly configured chamber and performs substrate processing on the substrate W in the depressurized chamber. Further, the substrate processing apparatus 60 may be a coater, such as a spin coater, that performs substrate processing, such as film formation, on the substrate W at ambient atmospheric pressure. The substrate processing apparatus 60 has partly the same configuration as the measurement apparatus 10 illustrated in FIG. 1; therefore, the same components are denoted by the same reference symbols and explanation thereof will be omitted, and differences will mainly be described.

The substrate processing apparatus 60 includes the stage 30 and the direct-current power supply 48. The electrostatic chuck 20 is provided on the stage 30.

The direct-current power supply 48 is connected to the electrostatic electrode 23 of the electrostatic chuck 20 via the wire 49. The direct-current power supply 48 applies voltage to the electrostatic electrode 23 via the wire 49. The electrostatic chuck 20 adsorbs the substrate W by application of voltage from the direct-current power supply 48 to the electrostatic electrode 23.

On the placing surface 21 of the electrostatic chuck 20, the substrate W is conveyed and placed by a transfer mechanism 61, such as a conveying arm. The transfer mechanism 61 includes, on a leading end side, a pick 62, and holds and transfers the substrate W by the pick 62. Further, the transfer mechanism 61 is configured to be able to press the substrate W placed on the electrostatic chuck 20 by a leading end of the pick 62. The transfer mechanism 61 includes, on the pick 62, a pressure sensor 63 that is able to measure pressure at the time of pressing the substrate W.

The substrate processing apparatus 60 includes a controller 70. A user interface 71 and a storage 72 are connected to the controller 70.

The user interface 71 includes an operation unit, such as a keyboard, that allows a user to perform command input operation for operating the substrate processing apparatus 60, and a display unit, such as a display, that visualizes and displays an operating state and a measurement result of the substrate processing apparatus 60.

The storage 72 stores therein a control program (software) for executing various kinds of processing performed by the substrate processing apparatus 60 and data, such as processing parameters. For example, the storage 72 stores therein applied voltage data indicating a voltage value that is applied in the adsorbed state. The voltage value of the applied voltage data is set so as to be able to achieve predetermined adsorption force with which the substrate W can be held stably. Meanwhile, the control program and the data may be stored in a computer readable computer recording medium. Further, the control program and the data may be stored in a different apparatus and may be read and used online via a dedicated line, for example.

The controller 70 is, for example, a computer that includes a processor, a memory, and an input output interface. The controller 70 controls each of the units of the substrate processing apparatus 60 via the input output interface. For example, the controller 70 controls the direct-current power supply 48 to control voltage that is applied from the direct-current power supply 48 to the electrostatic electrode 23.

The controller 70 reads the control program and the data stored in the storage 72 onto a memory based on an instruction or the like from the user interface 71. The controller 70 controls each of the units of the substrate processing apparatus 60 via the input output interface based on the control program and performs various kinds of processing including calibration processing (to be described later).

Operation of the substrate processing apparatus 60 will be described below.

In the substrate processing apparatus 60, the transfer mechanism 61 transfers the substrate W and the substrate W is placed on the placing surface 21. The substrate processing apparatus 60 adsorbs, by the electrostatic chuck 20, the substrate W placed on the placing surface 21. For example, the controller 50 reads the applied voltage data from the storage 72, controls the direct-current power supply 48, applies voltage of the voltage value of the applied voltage data to the electrostatic electrode 23, and adsorbs the substrate W by the electrostatic chuck 20.

Here, the adsorption force of the electrostatic chuck 20 may vary even when voltage of the same voltage value is applied to the electrostatic electrode 23.

To cope with this, the substrate processing apparatus 60 measures the adsorption force of the electrostatic electrode 23. For example, the controller 50 controls the direct-current power supply 48, applies voltage of the voltage value of the applied voltage data to the electrostatic electrode 23, and adsorbs the substrate W by the electrostatic chuck 20. The measurement apparatus 10 measures force needed to shift the substrate W adsorbed by the electrostatic chuck 20. For example, the pick 62 of the transfer mechanism 61 is pressed against a side surface of the substrate W. Meanwhile, when an edge ring is provided around the substrate W, the pressing is performed while the edge ring is removed.

FIG. 5 is a diagram schematically illustrating a state in which the transfer mechanism 61 presses the side surface of the substrate W. The controller 70 causes the pressure sensor 63 to measure pressure at which the substrate W starts to move in the adsorbed state. The pressure at which the substrate W starts to move corresponds to the force that is needed for the substrate W to start to move.

Here, the force needed for the substrate W to start to move in the adsorbed state is denoted by F, the adsorption force of the electrostatic chuck 20 is denoted by N, and a dynamic friction coefficient between the electrostatic chuck 20 and the substrate W is denoted by μ. In this case, a relationship represented by Expression (4) below holds.

$$F = μ / N \qquad ( 4 )$$

Expression (4) can be transformed into Expression (5) below.

$$N = F / μ \qquad ( 5 )$$

The substrate processing apparatus 60 calculates the adsorption force N of the electrostatic chuck 20. For example, the controller 70 calculates the adsorption force N of the electrostatic chuck 20 by Expression (5) based on force F needed for the substrate W to start to move in the adsorbed state and the dynamic friction coefficient μ of the electrostatic chuck 20. The dynamic friction coefficient μ of the electrostatic chuck 20 may be input from the user interface 51 or may be stored in advance in the storage 52. The dynamic friction coefficient μ of the electrostatic chuck 20 can be obtained by the measurement apparatus 10 of the first embodiment as described above. The dynamic friction coefficient μ may be changed over time. For example, dynamic friction coefficient data in which the dynamic friction coefficient μ of the electrostatic chuck 20 is determined for each number of times of substrate processing or each number of the substrates W subjected to the substrate processing is stored in the storage 72. The controller 70 counts the number of times of the substrate processing or the number of substrates subjected to the processing after replacement with the new electrostatic chuck 20. When calculating the adsorption force N, the controller 70 may obtain, from the dynamic friction coefficient data, the dynamic friction coefficient μ corresponding to the number of times of processing or the number of substrates subjected to the processing at that time, and calculate the adsorption force N of the electrostatic chuck 20 by using the obtained dynamic friction coefficient μ.

The substrate processing apparatus 60 calibrates the adsorption force N of the electrostatic chuck 20 by correcting the applied voltage data so as to achieve predetermined adsorption force with which the substrate W can be held stably. For example, when the calculated adsorption force N is lower than the predetermined adsorption force, the controller 70 corrects the applied voltage data so as to increase the adsorption force. For example, the controller 70 performs correction so as to increase the voltage value of the applied voltage data. Meanwhile, it may be possible to store, in advance in the storage 72, correction data in which the correction value of the voltage value is determined for each difference of the adsorption force from the predetermined adsorption force. The controller 70 may obtain, from the correction data, a correction value corresponding to a difference between the predetermined adsorption force and the calculated adsorption force N, and correct the voltage value of the applied voltage data by the obtained correction value.

### Flow of Calibration Processing

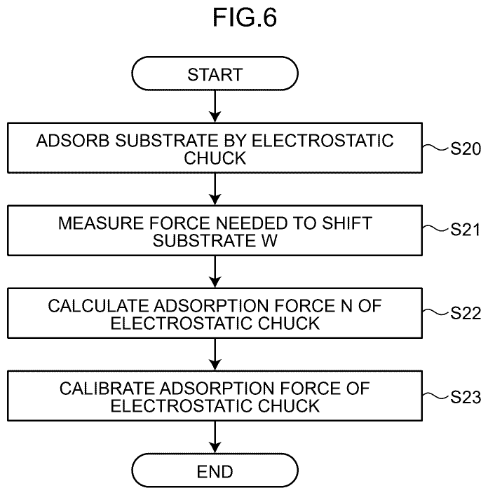

A flow of calibration processing including the calibration method of the present disclosure will be described below. FIG. 6 is a flowchart illustrating an example of a flow of calibration processing according to the second embodiment.

The transfer mechanism 61 transfers the substrate W and places the substrate W on the placing surface 21.

The substrate processing apparatus 60 adsorbs the substrate W placed on the placing surface 21 by the electrostatic chuck 20 (Step S20). For example, the controller 50 controls the direct-current power supply 48, applies voltage of the voltage value of the applied voltage data to the electrostatic electrode 23, and adsorbs the substrate W by the electrostatic chuck 20.

The measurement apparatus 10 measures force needed to shift the substrate W adsorbed by the electrostatic chuck 20 (Step S21). For example, the pick 62 of the transfer mechanism 61 is pressed against the side surface of the substrate W. The controller 70 causes the pressure sensor 63 to measure the force F needed for the substrate W to start to move in the adsorbed state.

The measurement apparatus 10 calculates the adsorption force N of the electrostatic chuck 20 (Step S22). For example, the controller 70 calculates the adsorption force N of the electrostatic chuck 20 by Expression (5) based on the force F needed for the substrate W to start to move in the adsorbed state and the dynamic friction coefficient μ of the electrostatic chuck 20.

The substrate processing apparatus 60 calibrates the adsorption force N of the electrostatic chuck 20 by correcting the applied voltage data so as to achieve predetermined adsorption force with which the substrate W can be held stably (Step S23), and terminates the process. For example, when the calculated adsorption force N is lower than the predetermined adsorption force, the controller 70 corrects the applied voltage data so as to increase the adsorption force.

Meanwhile, the method of measuring the adsorption force of the present disclosure allows to measure the adsorption force in any of an atmospheric pressure environment and a decompression environment. The measurement apparatus 10 and the substrate processing apparatus 60 may be configured to measure the adsorption force in the decompression environment, such as inside of a decompressed chamber.

Furthermore, in the embodiments as described above, the example has been described in which the electrostatic chuck 20 is adopted as the substrate adsorption unit and measures the adsorption force for electrostatically adsorbs the substrate W. However, the disclosed technology is not limited to this example. The substrate adsorption unit may be configured in an arbitrary manner as long as it is possible to adsorb a substrate. Moreover, the method of adsorbing the substrate W may be a different method, such as adsorption by suction.

Furthermore, in the first embodiment as described above, the example has been described in which the stage 30 to which the electrostatic chuck 20 is fixed is lifted to press the electrostatic chuck 20 against the substrate W that is fixed to the lower surface of the substrate holding plate 31. However, the disclosed technology is not limited to this example. For example, the substrate holding plate 31 may be lowered to press the substrate W against the electrostatic chuck 20.

Moreover, in the first embodiment as described above, the example has been described in which the stage 30 to which the electrostatic chuck 20 is fixed is rotated to measure the force needed to shift the substrate W on the electrostatic chuck 20. However, the disclosed technology is not limited to this example. For example, it may be possible to rotate the substrate holding plate 31 to which the substrate W is fixed and measure the force needed to shift the substrate W on the electrostatic chuck 20.

According to an aspect of embodiments, it is possible to quantitatively measure adsorption force with good reproducibility.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A measurement apparatus comprising:
a measurement unit that is able to measure force needed to shift a substrate on a substrate adsorption unit that is able to adsorb the substrate, in an adsorbed state in which the substrate is adsorbed by the substrate adsorption unit; and
a controller that calculates adsorption force of the substrate adsorption unit based on the force measured by the measurement unit.

2. The measurement apparatus according to claim 1, further comprising:
a pressing mechanism that is able to press the substrate against the substrate adsorption unit;
a pressure measurement unit that is able to measure pressure at which the pressing mechanism presses the substrate against the substrate adsorption unit; and
a rotation mechanism that is able to rotate the substrate adsorption unit, wherein
the measurement unit measures torque for rotating the substrate adsorption unit, and
the controller causes the pressing mechanism to press the substrate against the substrate adsorption unit, causes the rotation mechanism to apply force for rotating the substrate adsorption unit in both of the adsorbed state and a non-adsorbed state in which the substrate is not adsorbed by the substrate adsorption unit, causes the measurement unit to measure torque at which the substrate adsorption unit starts to rotate, causes the pressure measurement unit to measure pressure at which the substrate is pressed against the substrate adsorption unit, and calculates adsorption force of the substrate adsorption unit from torque in the adsorbed state and torque and the pressure in the non-adsorbed state.

3. The measurement apparatus according to claim 2, wherein the controller calculates adsorption force N of the substrate adsorption unit by Expression (1) below,
$$N = P ( {T}^{′} / T - 1 ) \qquad ( 1 )$$
where T represents the torque in the adsorbed state, T′ represents the torque in the non-adsorbed state, and P represents the pressure.

4. The measurement apparatus according to claim 2, wherein the controller calculates a dynamic friction coefficient of the substrate adsorption unit from a diameter of the substrate and the torque and the pressure in the adsorbed state.

5. The measurement apparatus according to claim 4, wherein the controller calculates a dynamic friction coefficient μ of the substrate adsorption unit by Expression (2) below,
$$μ = ( 2 / D / P ) / T \qquad ( 2 )$$
where D represents the diameter of the substrate, T represents the torque in the adsorbed state, and P represents the pressure.

6. The measurement apparatus according to claim 1, wherein the controller causes the measurement unit to measure force needed for the substrate to be pressed against a side surface and start to move in the adsorbed state, and calculates the adsorption force of the substrate adsorption unit from the force needed for the substrate to start to move in the adsorbed state and a dynamic friction coefficient of the substrate adsorption unit.

7. The measurement apparatus according to claim 6, wherein the controller calculates adsorption force N of the substrate adsorption unit by Expression (3) below,
$$N = F / μ \qquad ( 3 )$$
where F represents the force needed to start to move and μ represents the dynamic friction coefficient of the substrate adsorption unit.

8. A measurement method comprising:
measuring force needed to shift a substrate on a substrate adsorption unit that is able to adsorb the substrate, in an adsorbed state in which the substrate is adsorbed by the substrate adsorption unit; and
calculating adsorption force of the substrate adsorption unit based on the measured force.

9. A calibration method comprising:
measuring force needed to shift a substrate on a substrate adsorption unit that is able to adsorb the substrate, in an adsorbed state in which the substrate is adsorbed by the substrate adsorption unit;
calculating adsorption force of the substrate adsorption unit based on the measured force; and
calibrating adsorption force of the substrate adsorption unit based on the calculated adsorption force.

10. The calibration method according to claim 9, wherein
the substrate adsorption unit includes a built-in electrode,
force for adsorbing the substrate by the substrate adsorption unit varies in accordance with voltage applied to the electrode, and
the calibrating includes correcting a voltage value of the voltage applied to the electrode so as to achieve predetermined adsorption force based on the calculated adsorption force.
